(19) United States
(12) Patent Application Publication
(10) Pub. No.: US 2007/0253457 A1
(43) Pub. Date: Nov. 1, 2007

(54) Semiconductor laser device and method for fabricating the same

(76) Inventors: Takayuki Kashima, Okayama (JP); Kouji Makita, Hyogo (JP)

Correspondence Address: MCDERMOTT WILL & EMERY LLP, 600 13TH STREET, N.W., WASHINGTON, DC, 20005-3096, US

(21) Appl. No.: 11/637,098

(22) Filed: Dec. 12, 2006

(30) Foreign Application Priority Data
Apr. 26, 2006 (JP) 2006-121910

(51) Int. Cl. H01S 5/00

(52) U.S. Cl. 372/50.121; 372/46.01

(57) ABSTRACT

A first semiconductor laser emitting light with a first wavelength and a second semiconductor laser emitting light with a second wavelength are formed on an identical substrate. Each of the semiconductor lasers includes: a doublehetero structure in which at least a first-conductivity-type cladding layer, an active layer and a second-conductivity-type cladding layer are stacked in this order; and a ridge waveguide including at least an upper portion of the second-conductivity-type cladding layer and a contact layer formed on the second-conductivity-type cladding layer. A first-conductivity-type current blocking layer is formed on both side walls of each of the ridge waveguides and on a portion around each of the ridge waveguides, and a leakage preventing layer is formed on the current blocking layer.

### BACKGROUND OF THE INVENTION

(1) Field of the Invention

The present invention relates to semiconductor laser devices and methods for fabricating the devices, and particularly relates to a multiwavelength semiconductor laser device with a monolithic structure including a plurality of semiconductor lasers having different oscillation wavelengths and a method for fabricating the device.

(2) Background Art

DVD drives for recording/playing back optical information characterized by large memory capacity have become rapidly widespread in various fields such as video players in recent years. In addition, reading from conventionally-used CDs, CD-Rs and CD-RWs using the same equipment are strongly needed. Therefore, infrared semiconductor lasers at a 780-nm band for CDs are used as light sources for optical pickups for use in recording and playback of DVDs or CDs, together with red semiconductor lasers at a 650-nm band for DVDs.

Size reduction of information processors such as personal computers involves the need for facilitating size and thickness reduction of recording/playing back devices for, for example, DVDs. To meet the need, size and thickness reduction of optical pickups are indispensable. For the size and thickness reduction of optical pickups, it is effective to reduce the number of optical parts so as to simplify the device. A method for achieving the size and thickness reduction is integration of a red semiconductor laser and an infrared semiconductor laser.

Monolithic two-wavelength semiconductor laser devices in each of which a red semiconductor laser and an infrared semiconductor laser are integrated on the same semiconductor substrate are implemented in recent years. Accordingly, a plurality of semiconductor lasers are allowed to be integrated as one unit and, in addition, the red semiconductor laser and the infrared semiconductor laser share optical parts such as a collimator lens and a beam splitter, thus achieving size and thickness reduction of the resultant device.

These monolithic two-wavelength semiconductor laser devices require further increase in optical output power and further cost reduction. To achieve the cost reduction, simplification of the structure and increase of the chip yield are needed.

However, fabrication processes of a monolithic semiconductor laser are complicated as compared to fabrication processes of a conventional laser that emits a single beam, so that simplification of the structure and increase in yield are required. In recent years, lasers which do not need burying and growth are also developed for monolithic two-wavelength lasers, as disclosed in Patent Literature 1, for example.

FIGS. 10A and 10B, FIGS. 11A and 11B and FIGS. 12A and 12B are cross-sectional views showing respective process steps of a method for fabricating a conventional semiconductor laser device disclosed in Patent Literature 1.

First, as illustrated in FIG. 10A, an n-type buffer layer 302, an n-type cladding layer 303, an active layer 304, a p-type first cladding layer 305, a p-type etching stopper layer 306, a p-type second cladding layer 307, a p-type intermediate layer 308 and a p-type contact layer 309 are sequentially formed by metal organic chemical vapor deposition (MOCVD) over an n-type substrate 301.

Next, as illustrated in FIG. 10B, a portion associated with a red-laser region in the multilayer semiconductor structure formed in the process step shown in FIG. 10A is removed by photolithography and wet etching, thereby forming an infrared-laser multilayer semiconductor structure 310.

Then, as illustrated in FIG. 11A, an n-type buffer layer 312, an n-type cladding layer 313, an active layer 314, a p-type first cladding layer 315, a p-type etching stopper layer 316, a p-type second cladding layer 317, a p-type intermediate layer 318 and a p-type contact layer 319 are sequentially formed by MOCVD over the n-type substrate 301 including the infrared-laser multilayer semiconductor structure 310.

Thereafter, as illustrated in FIG. 11B, a portion associated with an infrared-laser region in the multilayer semiconductor structure formed in the process step shown in FIG. 11A is removed by photolithography and wet etching, thereby forming a red-laser multilayer semiconductor structure 320. To separate an infrared laser and a red laser from each other, an isolation trench 330 is formed between the infrared-laser multilayer semiconductor structure 310 and the red-laser multilayer semiconductor structure 320. At this time, trenches (hereinafter, also referred to as isolation trenches 330) are also formed between the multilayer semiconductor structures 310 and 320 and respective ends of the substrate.

Subsequently, a SiO₂ film (not shown) is formed on the infrared-laser multilayer semiconductor structure 310 and the red-laser multilayer semiconductor structure 320, and then is patterned by photolithography and dry etching, thereby forming a mask pattern (not shown) covering a ridge-waveguide region in the shape of a stripe for each of an infrared laser and a red laser and also covering supporter regions at both sides of the ridge-waveguide region. Thereafter, using the mask pattern, the p-type contact layer 309, the p-type intermediate layer 308 and the p-type second cladding layer 307 of the infrared laser and the p-type contact layer 319, the p-type intermediate layer 318 and the p-type second cladding layer 317 of the red laser are etched until the p-type etching stopper layer 306 and the p-type etching stopper layer 316 are exposed, thereby forming a ridge waveguide 350 of the infrared laser, supporters 351 and 352 at both side of the ridge waveguide 350, a ridge waveguide 360 of the red laser and supporters 361 and 362 at both sides of the ridge waveguide 360, as illustrated in FIG. 12A.

Then, as illustrated in FIG. 12B, a current blocking layer 332 is formed over the entire surface of the n-type substrate 301. Thereafter, using photolithography and etching, portions of the current blocking layer 332 located on the ridge waveguides 350 and 360 and a portion of the current blocking layer 332 located in the isolation trench 330 are removed. In the process step shown in FIG. 12B, the supporters 351 and 352 or the supporters 361 and 362 are formed at both sides of each of the ridge waveguides 350 and 360, so that the thickness of a resist film formed around the ridge waveguides 350 and 360 in the photolithography process is uniform. Accordingly, accuracy in processing the current blocking layer 332 increases.

Lastly, though not shown, a p-side electrode is formed at the surface of the n-type substrate 301 on which the multilayer semiconductor structures 310 and 320 are formed, whereas an n-side electrode is formed at the back surface of the n-type substrate 301.

### Patent Literature 1

Japanese Unexamined Patent Publication No. 2005-268475

### SUMMARY OF THE INVENTION

However, when a monolithic two-wavelength semiconductor laser device is fabricated by the method disclosed in Patent Literature 1, it is difficult to obtain a high yield.

It is therefore an object of the present invention to provide a monolithic multiwavelength semiconductor laser device with a high yield and a method for fabricating the device.

To achieve the object, the present inventors studied a cause of decrease in yield occurring when a monolithic two-wavelength semiconductor laser device is fabricated by the method disclosed in Patent Literature 1, to obtain the following findings.

In fabricating a monolithic two-wavelength semiconductor laser device, particles are generated during crystal growth of semiconductor layers for an infrared laser and a red laser in some cases. The number of particles formed during the crystal growth tends to increase with time and it is difficult to suppress the formation of particles. In addition, to obtain higher output power of the lasers, the thickness of the semiconductor layers also tends to increase, resulting in that particles are more likely to be generated.

The size of particles generated during crystal growth reaches the same size as the deposition thickness of the semiconductor layers in some cases. In such cases, a level difference formed after formation of the semiconductor layers becomes large, so that this level difference is insufficiently covered with the resist mask during lithography in processing. As a result, when particles are removed by etching, the semiconductor layers are likely to be also removed by etching with an etchant entering the space where the particles were present. In particular, when the semiconductor layers are etched and the substrate is then exposed, the p-side electrode is directly formed in the hole formed in the semiconductor layers by the etching with the n-type current blocking layer interposed therebetween. Accordingly, a short circuit failure occurs between this p-side electrode and the n-side electrode formed at the back surface of the n-type substrate, resulting in decrease of the yield.

FIG. 13A shows a state in which a resist pattern 351 is formed by photolithography after generation of particles 350 in the infrared-laser region in a semiconductor-layer formation step shown in FIG. 10A of the method for fabricating a conventional semiconductor laser device. As illustrated in FIG. 13A, a portion of the infrared-laser region where the particles 350 are generated is not covered with the resist pattern 351.

FIG. 13B shows a state in which the particles 350 shown in FIG. 13A are removed by etching in the step of forming the infrared-laser multilayer semiconductor structure 310 shown in FIG. 10B in the method for fabricating a conventional semiconductor laser device. As illustrated in FIG. 13B, the multilayer semiconductor structure 310 is removed by etching with an etchant entering a portion where the particles 350 have been removed, resulting in that a hole 352 reaching the n-type substrate 301 is disadvantageously formed. At this time, an n-type current blocking layer 332 (see FIG. 12B) is formed in this hole. If a p-side electrode is formed directly thereon, a short circuit failure occurs between this p-side electrode and the n-side electrode formed at the back surface of the n-type substrate 301.

Based on the foregoing findings, the present inventors have reached the invention that prevents a short circuit failure from occurring due to etching of particles generated during crystal growth and, thereby, increases the yield of a monolithic multiwavelength semiconductor laser device at low cost, using a structure in which a leakage preventing layer is formed on a current blocking layer.

Specifically, a first semiconductor laser device according to the present invention is a monolithic semiconductor laser device formed by integrating a first semiconductor laser emitting light with a first wavelength and a second semiconductor laser emitting light with a second wavelength on an identical substrate. Each of the first semiconductor laser and the second semiconductor laser includes: a doublehetero structure in which at least a first-conductivity-type cladding layer, an active layer and a second-conductivity-type cladding layer are stacked in this order; and a ridge waveguide including at least an upper portion of the second-conductivity-type cladding layer and a contact layer formed on the second-conductivity-type cladding layer. A first-conductivity-type current blocking layer is formed on both side walls of each of the ridge waveguides and on a portion around each of the ridge waveguides. A leakage preventing layer is formed on the current blocking layer.

In the first semiconductor laser device, the leakage preventing layer is formed on the current blocking layer formed on both side walls of each of the ridge waveguides and on a portion around each of the ridge waveguides. Accordingly, even when a hole is formed in semiconductor layers forming a laser by etching particles generated during crystal growth of the semiconductor layers through a large number of etching processes, the leakage preventing layer is formed in this hole. Therefore, even in such a case where the current blocking layer is formed in a hole reaching the substrate and then a substrate-surface-side electrode is formed, this substrate-surface-side electrode and the current blocking layer are insulated from each other by the leakage preventing layer, thus preventing a short circuit failure from occurring between the substrate-surface-side electrode and a substrate-back-surface-side electrode. That is, in the first semiconductor laser device of the present invention, a simple structure in which the leakage preventing layer is formed on the current blocking layer prevents a short circuit failure from occurring due to etching of particles generated during crystal growth. Accordingly, a monolithic multiwavelength semiconductor laser device achieving a high yield at low cost is implemented.

In the first semiconductor laser device, in a case in which a hole reaching at least the active layer is formed in the doublehetero structure of at least one of the first semiconductor laser and the second semiconductor laser, and particularly in a case in which the hole reaches the substrate, the foregoing advantages are obtained.

In the first semiconductor laser device, if the leakage preventing layer has a thickness of 0.1 μm or more, the foregoing advantages are further ensured.

In the first semiconductor laser device, if the leakage preventing layer is one of single-layer films made of Si, SiN, SiO₂, TiO₂, Ta₂O₅, NbO and amorphous Si hydride, respectively, or a multilayer film made of a stack of two or more of the single-layer films, the foregoing advantages are ensured.

In the first semiconductor laser device, if the leakage preventing layer is deposited over the current blocking layer except for portions of the current blocking layer formed on both side walls of each of the ridge waveguides, and particularly if the leakage preventing layer is deposited over a portion of the current blocking layer at least 1 μm apart from each of the ridge waveguides, stress from the leakage preventing layer to the current blocking layer is reduced, so that reliability degradation of the lasers is prevented.

In the first semiconductor laser device, if the leakage preventing layer is also formed in a trench separating the first semiconductor laser and the second semiconductor laser from each other, even when solder flows into the trench after formation of a laser, characteristic deterioration of the laser is prevented because the trench is covered with the leakage preventing layer.

In the first semiconductor laser device, if the leakage preventing layer has a resistivity of 3.0×10³ Ω·m or more, the advantage of the present invention, i.e., prevention of a short circuit failure caused by etching of particles generated during crystal growth, is ensured.

In the first semiconductor laser device, if the current blocking layer is a semiconductor layer, heat dissipation during operation is ensured as compared to the case of using a dielectric film. In this case, if the current blocking layer is a multilayer film formed by alternately stacking at least one n-type semiconductor layer and at least one p-type semiconductor layer, advantages of the leakage preventing layer of the present invention are noticeable.

In the first semiconductor laser device, if the first-conductivity-type cladding layer and the second-conductivity-type cladding layer included in each of the first semiconductor laser and the second semiconductor laser are made of materials containing an identical element, the number of process steps which can be shared increases, thereby simplifying the method.

In the first semiconductor laser device, if the first-conductivity-type cladding layer and the second-conductivity-type cladding layer included in each of the first semiconductor laser and the second semiconductor laser are made of materials containing phosphorus, a wider bandgap than that in the case of using an As-based cladding layer, which is generally used together with an As-based active layer, is obtained. This promotes a carrier confinement effect, so that temperature characteristics are enhanced.

In the first semiconductor laser device, the light with the first wavelength may be infrared light, and the light with the second wavelength may be red light.

A second semiconductor laser device according to the present invention is a monolithic semiconductor laser device formed by integrating a first semiconductor laser emitting light with a first wavelength and a second semiconductor laser emitting light with a second wavelength on an identical substrate. Each of the first semiconductor laser and the second semiconductor laser includes: a doublehetero structure in which at least a first-conductivity-type cladding layer, an active layer and a second-conductivity-type cladding layer are stacked in this order; a ridge waveguide including at least an upper portion of the second-conductivity-type cladding layer and a contact layer formed on the second-conductivity-type cladding layer; and a supporter including at least an upper portion of the second-conductivity-type cladding layer and located at each side of the ridge waveguide at a given distance. A first-conductivity-type current blocking layer is formed on both side walls of each of the ridge waveguides, on a side wall of each of the supporters toward an associated one of the ridge waveguides and between each of the supporters and an associated one of the ridge waveguides. A leakage preventing layer is formed on the current blocking layer.

The second semiconductor laser device has advantages similar to those of the first semiconductor laser device.

A method for fabricating a semiconductor laser device according to the present invention includes the steps of: (a) forming a first multilayer semiconductor structure in which at least a first first-conductivity-type cladding layer, a first active layer, a first second-conductivity-type cladding layer and a first second-conductivity-type contact layer are stacked in this order over a first semiconductor laser region of a substrate; (b) forming a second multilayer semiconductor structure in which at least a second first-conductivity-type cladding layer, a second active layer, a second second-conductivity-type cladding layer and a second second-conductivity-type contact layer are stacked in this order over a second semiconductor laser region of the substrate; (c) patterning at least an upper portion of the first second-conductivity-type cladding layer and the first second-conductivity-type contact layer, thereby forming a first ridge waveguide, and patterning at least an upper portion of the second second-conductivity-type cladding layer and the second second-conductivity-type contact layer, thereby forming a second ridge waveguide; (d) forming a current blocking layer on both side walls of the first ridge waveguide, a portion around the first ridge waveguide, both side walls of the second ridge waveguide and a portion around the second ridge waveguide; and (e) forming a leakage preventing layer on the current blocking layer.

With the method of the present invention, the leakage preventing layer is formed on the current blocking layer formed on both side walls of the ridge waveguide of each laser and on a portion around each of the ridge waveguides. Accordingly, even when a hole is formed in semiconductor layers forming a laser by etching particles generated during crystal growth of the semiconductor layers through a large number of etching processes, the leakage preventing layer is formed in this hole. Therefore, even in such a case where the current blocking layer is formed in a hole reaching the substrate and then a substrate-surface-side electrode is formed, this substrate-surface-side electrode and the current blocking layer are insulated from each other by the leakage preventing layer, thus preventing a short circuit failure from occurring between the substrate-surface-side electrode and a substrate-back-surface-side electrode. That is, with the method of the present invention, a simple structure in which the leakage preventing layer is formed on the current blocking layer prevents a short circuit failure from occurring due to etching of particles generated during crystal growth. Accordingly, a monolithic multiwavelength semiconductor laser device achieving a high yield at low cost is implemented.

In the method, the step (c) preferably includes the step of forming a first supporter including at least an upper portion of the first second-conductivity-type cladding layer at each side of the fist ridge waveguide and forming a second supporter including at least an upper portion of the second second-conductivity-type cladding layer at each side of the second ridge waveguide. Then, the thickness of a resist film formed around each of the ridge waveguides in a photolithography process for forming a current blocking layer is uniform. Accordingly, accuracy in processing the current blocking layer increases. In this case, the method preferably further includes, before the step (d), the step (f) of removing a portion of the first second-conductivity-type contact layer in the first ridge waveguide near an end face of a resonator of the first semiconductor laser, a portion of the first second-conductivity-type contact layer formed on the first supporter, a portion of the second second-conductivity-type contact layer in the second ridge waveguide near an end face of a resonator of the second semiconductor laser and a portion of the second second-conductivity-type contact layer formed on the second supporter. Then, the second-conductivity-type contact layer near the end face of the resonator of each laser is removed, so that damage of the laser due to heat generation at the resonator end face of the laser during laser oscillation is prevented. In addition, portions of the second-conductivity-type contact layer formed on the supporters of each of the lasers are removed, so that the current blocking layer is grown on the supporters of each of the lasers with excellent crystallinity in a subsequent process step.

If the method further includes, after the step (e), the step (g) of removing portions of the leakage preventing layer formed at least on both side walls of the first ridge waveguide and on both side walls of the second ridge waveguide, and particularly if in the step (g), a portion of the leakage preventing layer in a range of 1 μm or more from each end of each of the first ridge waveguide and the second ridge waveguide is removed, stress from the leakage preventing film to the current blocking layer is reduced, so that reliability degradation of the lasers is prevented.

In the method, in the step (g), a portion of the leakage preventing layer near an end face of a resonator of each of the first semiconductor laser and the second semiconductor laser is preferably removed. Then, cleavage for forming the end faces of the resonators of the lasers is easily performed. In this case, in the step (g), if a portion of the leakage preventing layer in a range from 5 μm to 20 μm, both inclusive, from an end face of a resonator of each of the first semiconductor laser and the second semiconductor laser is removed, it is possible to ensure the advantage of the present invention that a short circuit failure caused by etching of particles generated during crystal growth is prevented, while obtaining the advantage that the cleavage is easily performed.

In the method, in the step (e), if the leakage preventing layer is also formed in a trench formed between the first multilayer semiconductor structure and the second multilayer semiconductor structure, even when solder flows into the trench after formation of a laser, characteristic deterioration of the lasers is prevented because the trench is covered with the leakage preventing layer.

As described above, according to the present invention, a simple structure in which the leakage preventing layer is formed on the current blocking layer prevents a short circuit failure from occurring due to etching of particles generated during crystal growth. Accordingly, a monolithic multiwavelength semiconductor laser device achieving a high yield at low cost is implemented.

That is, the present invention relates to a multiwavelength semiconductor laser device with a monolithic structure including a plurality of semiconductor lasers having different oscillation wavelengths and a method for fabricating the semiconductor laser device. In particular, the present invention is very useful especially in application to, for example, recording optical disk apparatus. In this application, it is possible to prevent a short circuit failure from occurring, because of etching processes for forming a monolithic structure of an infrared laser and a red laser, in the lasers through a hole reaching a substrate, so that low cost and a high yield are achieved.

### BRIEF DESCRIPTION OF THE DRAWINGS

FIG. 1 is a perspective view illustrating a structure of a semiconductor laser device according to an embodiment of the present invention.

FIG. 2A is a cross-sectional view taken along the line A-A′ in FIG. 1. FIG. 2B is a cross-sectional view taken along the line B-B′ in FIG. 1.

FIGS. 3A and 3B are cross-sectional views showing respective process steps of a method for fabricating a semiconductor laser device according to the embodiment.

FIG. 4 is a cross-sectional view showing a process step of the method for fabricating a semiconductor laser device of the embodiment.

FIGS. 5A and 5B are cross-sectional views showing respective process steps of the method for fabricating a semiconductor laser device of the embodiment.

FIG. 6A is a cross-sectional view of a gain region showing a process step of the method for fabricating a semiconductor laser device of the embodiment. FIG. 6B is a cross-sectional view near an end faces of resonators showing the process step.

FIG. 7A is a cross-sectional view of the gain region showing a process step of the method for fabricating a semiconductor laser device of the embodiment. FIG. 7B is a cross-sectional view near the end faces of the resonators showing the process step.

FIG. 8A is a cross-sectional view of the gain region showing a process step of the method for fabricating a semiconductor laser device of the embodiment. FIG. 8B is a cross-sectional view near end faces of the resonators showing the process step.

FIG. 9A is a cross-sectional view of the gain region showing a process step of the method for fabricating a semiconductor laser device of the embodiment. FIG. 9B is a cross-sectional view near the end faces of the resonators showing the process step.

FIGS. 10A and 10B are cross-sectional views showing respective process steps of a conventional method for fabricating a semiconductor laser device.

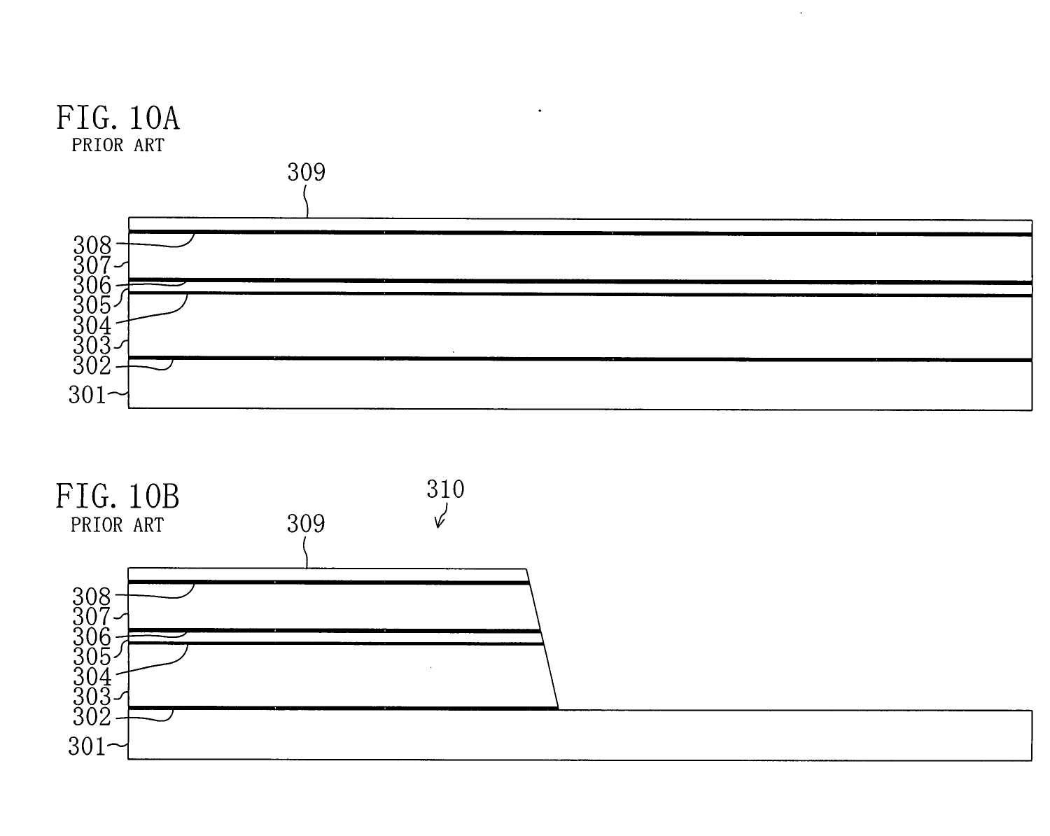

FIGS. 11A and 11B are cross-sectional views showing respective process steps of the conventional method for fabricating a semiconductor laser device.

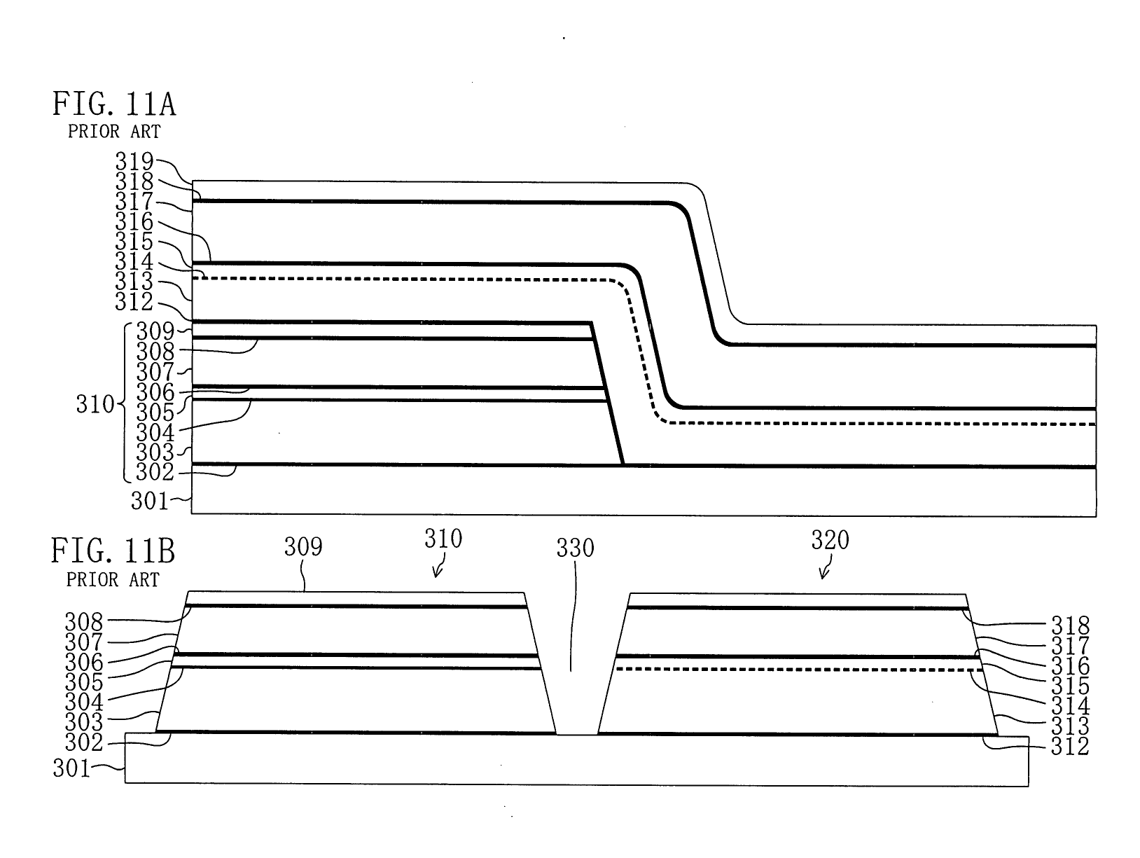

FIGS. 12A and 12B are cross-sectional views showing respective process steps of the conventional method for fabricating a semiconductor laser device.

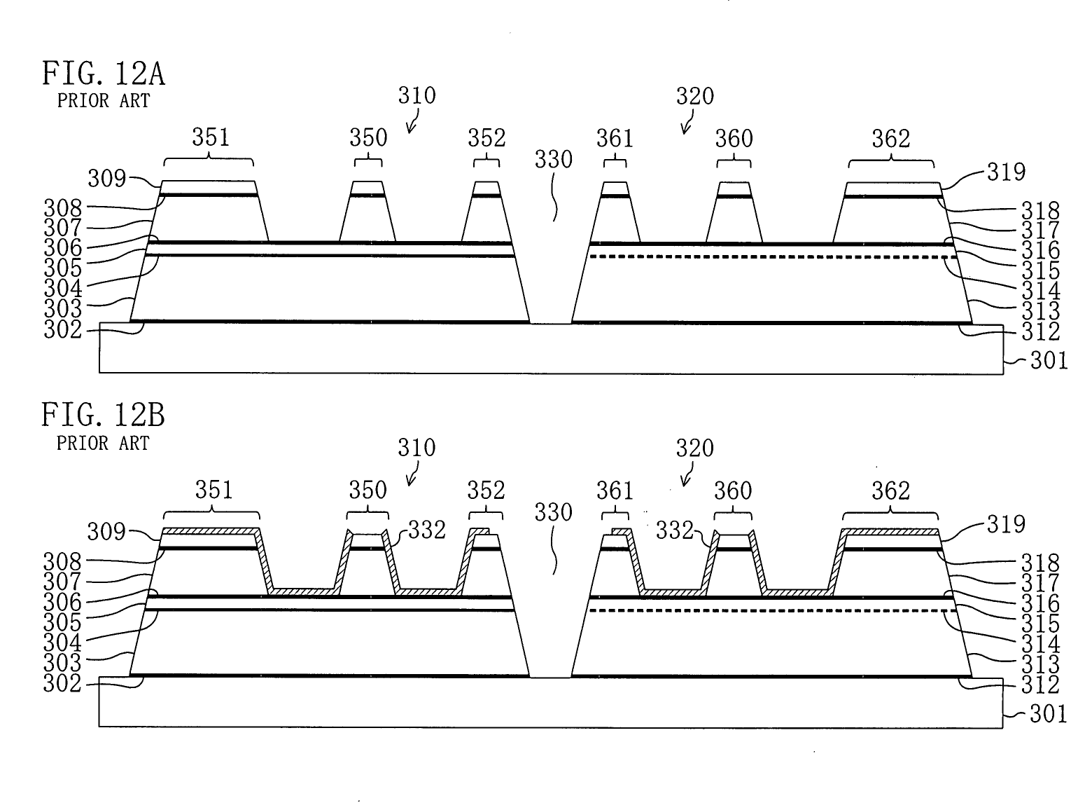

FIGS. 13A and 13B are views for explaining problems in the conventional method for fabricating a semiconductor laser device.

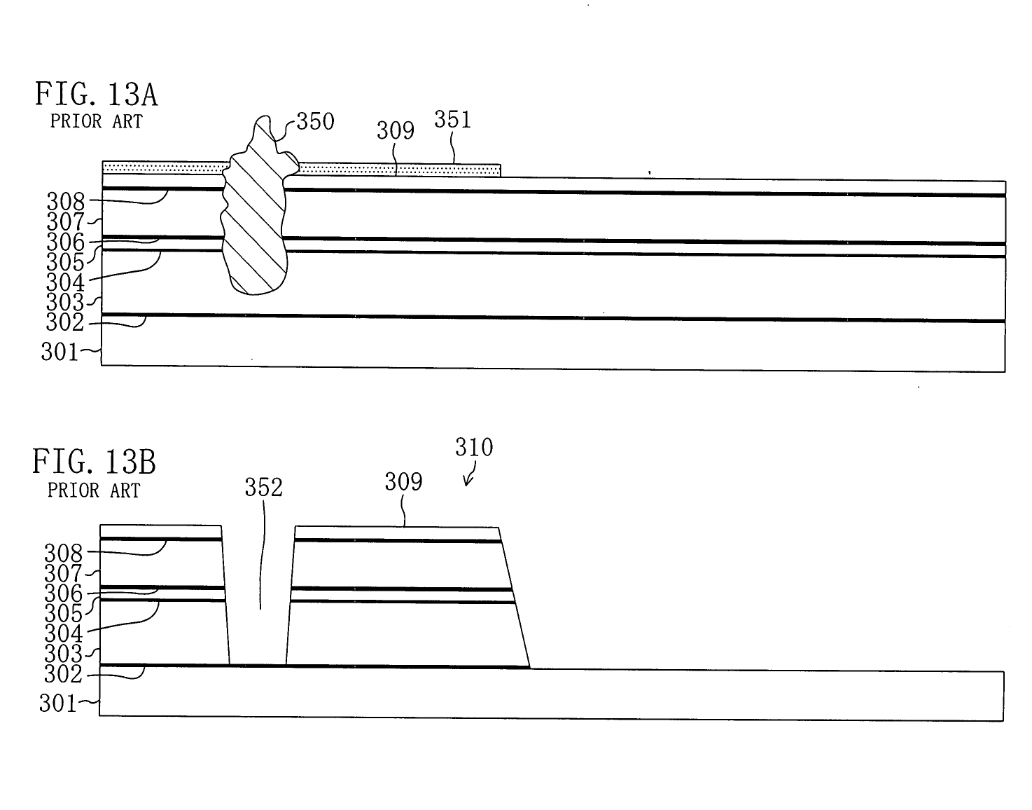

### DETAILED DESCRIPTION OF THE INVENTION

Hereinafter, a semiconductor laser device according to an embodiment of the present invention, specifically a monolithic two-wavelength semiconductor laser device, and a method for fabricating the device will be described with reference to the drawings.

### (Structure of Two-Wavelength Semiconductor Laser Device)

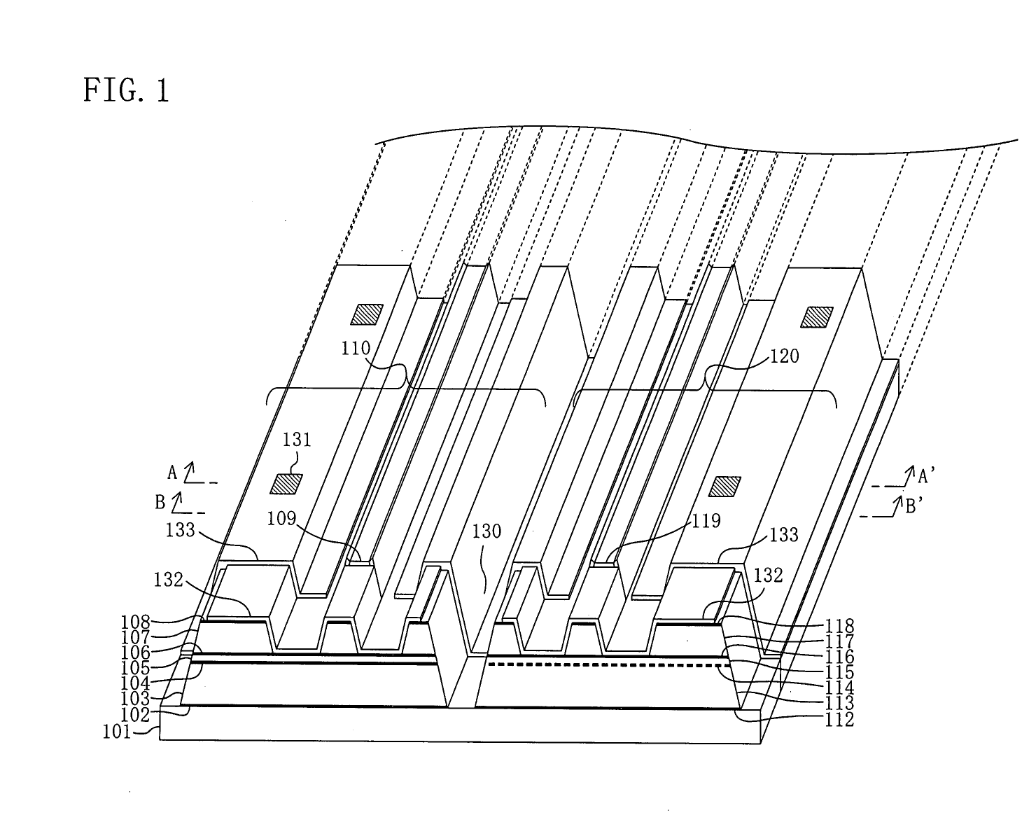

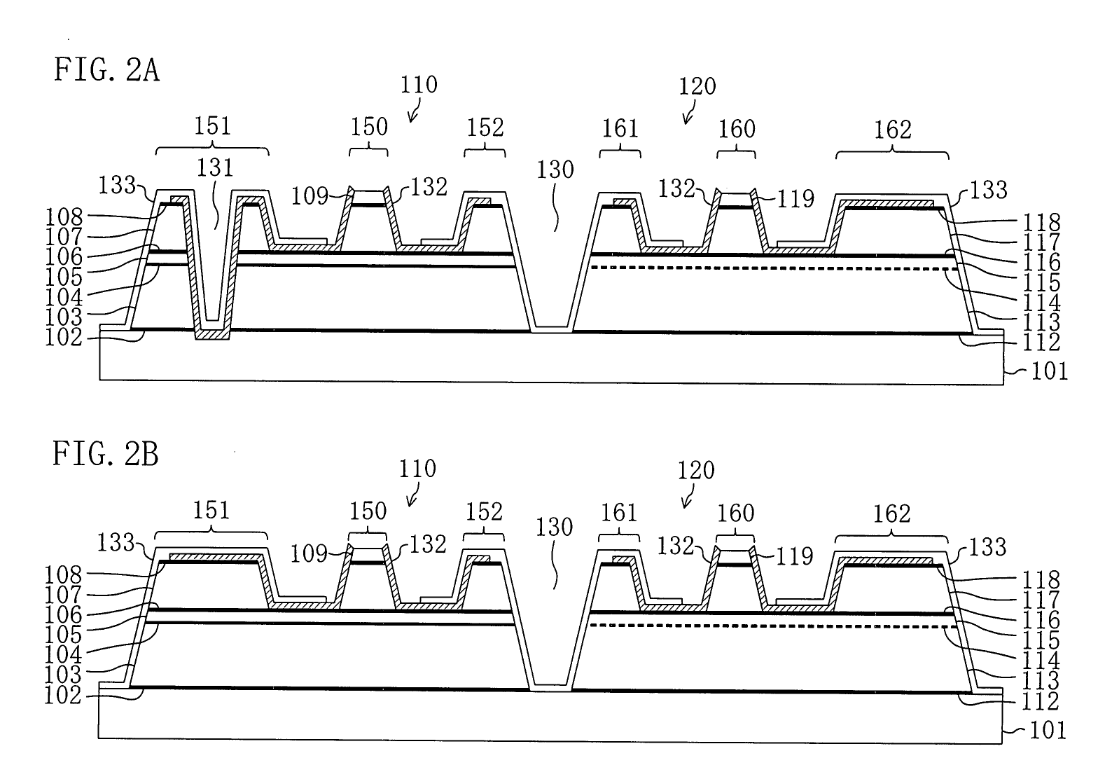

FIG. 1 is a perspective view illustrating a structure of a semiconductor laser device according to this embodiment. FIG. 2A is a cross-sectional view taken along the line A-A′ in FIG. 1 (i.e., a cross-sectional view across a hole formed by etching of particles generated during crystal growth). FIG. 2B is a cross-sectional view taken along the line B-B′ in FIG. 1 (i.e., a cross-sectional view not across the hole).

As illustrated in FIG. 1 and FIGS. 2A and 2B, the monolithic two-wavelength semiconductor laser device of this embodiment includes an infrared laser 110 and a red laser 120 on a substrate 101 made of, for example, n-type GaAs. The lasers have the following structures:

First, in the infrared laser 110, an n-type buffer layer 102 made of, for example, n-type GaAs, an n-type cladding layer 103 made of, for example, n-type (AlₓGa₁₋ₓ)_{y}In_{1-y}P (where 0<x<1 and 0<y<1), an active layer 104 made of, for example, a stack of a GaAs layer and an AlGaAs layer, a p-type first cladding layer 105 made of, for example, p-type (AlₓGa₁₋ₓ)_{y}In_{1-y}P (where 0<x<1 and 0<y<1), an etching stopper layer 106 made of, for example, p-type GaInP, a p-type second cladding layer 107 made of, for example, p-type (AlₓGa₁₋ₓ)_{y}In_{1-y}P (where 0<x<1 and 0<y<1), a p-type intermediate layer 108 made of, for example, p-type GaInP and a p-type contact layer 109 made of, for example, p-type GaAs are sequentially formed by, for example, MOCVD over the substrate 101.

The n-type cladding layer 103, the active layer 104 and the p-type first cladding layer 105 form a double heterostructure. The p-type second cladding layer 107, the p-type intermediate layer 108 and the p-type contact layer 109 are processed to form a mesa stripe serving as a ridge waveguide 150 for light confinement and current confinement in the horizontal/lateral direction. Supporters 151 and 152 formed out of the p-type second cladding layer 107 and the p-type intermediate layer 108 by patterning are provided at both sides of the ridge waveguide 150 at given intervals.

On the other hand, in the red laser 120, an n-type buffer layer 112 made of, for example, n-type GaAs, an n-type cladding layer 113 made of, for example, n-type (AlₓGa₁₋ₓ)_{y}In_{1-y}P (where 0<x<1 and 0<y<1), an active layer 114 made of, for example, a stack of a GaInP layer and an AlGaInP layer, a p-type first cladding layer 115 made of, for example, p-type (AlₓGa₁₋ₓ)_{y}In_{1-y}P (where 0<x<1 and 0<y<1), an etching stopper layer 116 made of, for example, p-type GaInP, a p-type second cladding layer 117 made of, for example, p-type (AlₓGa₁₋ₓ)_{y}In_{1-y}P (where 0<x<1 and 0<y<1), a p-type intermediate layer 118 made of, for example, p-type GaInP and a p-type contact layer 119 made of, for example, p-type GaAs are sequentially formed by, for example, MOCVD over the substrate 101.

The n-type cladding layer 113, the active layer 114 and the p-type first cladding layer 115 form a double heterostructure. The p-type second cladding layer 117, the p-type intermediate layer 118 and the p-type contact layer 119 are processed to form a mesa stripe serving as a ridge waveguide 160 for light confinement and current confinement in the horizontal/lateral direction. Supporters 161 and 162 formed out of the p-type second cladding layer 117 and the p-type intermediate layer 118 by patterning are provided at both sides of the ridge waveguide 160 at given intervals.

An isolation trench 130 reaching the substrate 101 is formed between the infrared laser 110 and the red laser 120, thereby electrically insulating the infrared laser 110 and the red laser 120 from each other. In addition, trenches (hereinafter, also referred to as isolation trenches 130) reaching the substrate 101 are also formed between the infrared laser 110 and the red laser 120 and respective ends of the substrate.

As illustrated in FIG. 1 and FIG. 2A, particles generated during crystal growth for forming the infrared laser 110 and the red laser 120 are etched, so that a plurality of holes 131 are formed in the lasers 110 and 120. The holes 131 are formed by etching which has proceeded below the active layers 104 and 114, for example.

As illustrated in FIG. 1 and FIGS. 2A and 2B, the side walls of the ridge waveguides 150 and 160, the upper faces and side walls toward the ridge waveguides of the supporters 151, 152, 161 and 162, a portion of the etching stopper layer 106 located between the ridge waveguide 150 and each of the supporters 151 and 152, a portion of the etching stopper layer 116 located between the ridge waveguide 160 and each of the supporters 161 and 162 are covered with a current blocking layer 132. In other words, portions of the current blocking layer 132 located on the upper faces of the ridge waveguides 150 and 160 and the inside and neighboring regions of the isolation trenches 130 are removed by etching. As shown in FIG. 2A, the current blocking layer 132 is also formed in the holes 131 in the formation region thereof.

The p-type contact layer 109 is completely removed by etching from the supporters 151 and 152, and the p-type contact layer 119 is completely removed by etching from the supporters 161 and 162. As illustrated in FIG. 1, a portion of the p-type contact layer 109 near an end face of the resonator is removed by etching from the ridge waveguide 150 of the infrared laser 110 and a portion of the p-type contact layer 119 near the end face of the resonator is removed by etching from the ridge waveguide 160 of the red laser 120. In addition, as illustrated in FIG. 1, the current blocking layer 132 is formed on the region where the p-type contact layer 109 has been removed near the end face of the resonator in the ridge waveguide 150 and on the region where the p-type contact layer 119 has been removed near the end face of the resonator in the ridge waveguide 160. The end face of the resonator is herein an end face of a laser in the direction along which the ridge waveguides 150 and 160 extend.

This embodiment is characterized in that a leakage preventing layer 133 made of, for example, a dielectric film is formed on the current blocking layer 132, as illustrated in FIG. 1 and FIGS. 2A and 2B. The leakage preventing layer 133 is also formed in the isolation trenches 130 where the current blocking layer 132 is not formed and on its neighboring region. Portions of the leakage preventing layer 133 near the end faces of the resonators are removed by etching. In other words, portions of the current blocking layer 132 near the end faces of the resonators are not covered with the leakage preventing layer 133 and are exposed.

With the foregoing characteristics of this embodiment, the leakage preventing layer 133 is also formed in the hole 131 in the formation region thereof, as illustrated in FIG. 2A.

In this embodiment, for example, a SiO₂ film with a thickness of 0.4 μm is used as the leakage preventing layer 133.

Advantages such as those obtained by formation of the leakage preventing layer 133 in the hole 131 and removal of portions of the p-type contact layers 109 and 119 and portions of the leakage preventing layer 133 near the end faces of the resonators as described above will be described below in the section for a method for fabricating a semiconductor laser device according to this embodiment.

### (Method for Fabricating Two-Wavelength Semiconductor Laser Device)

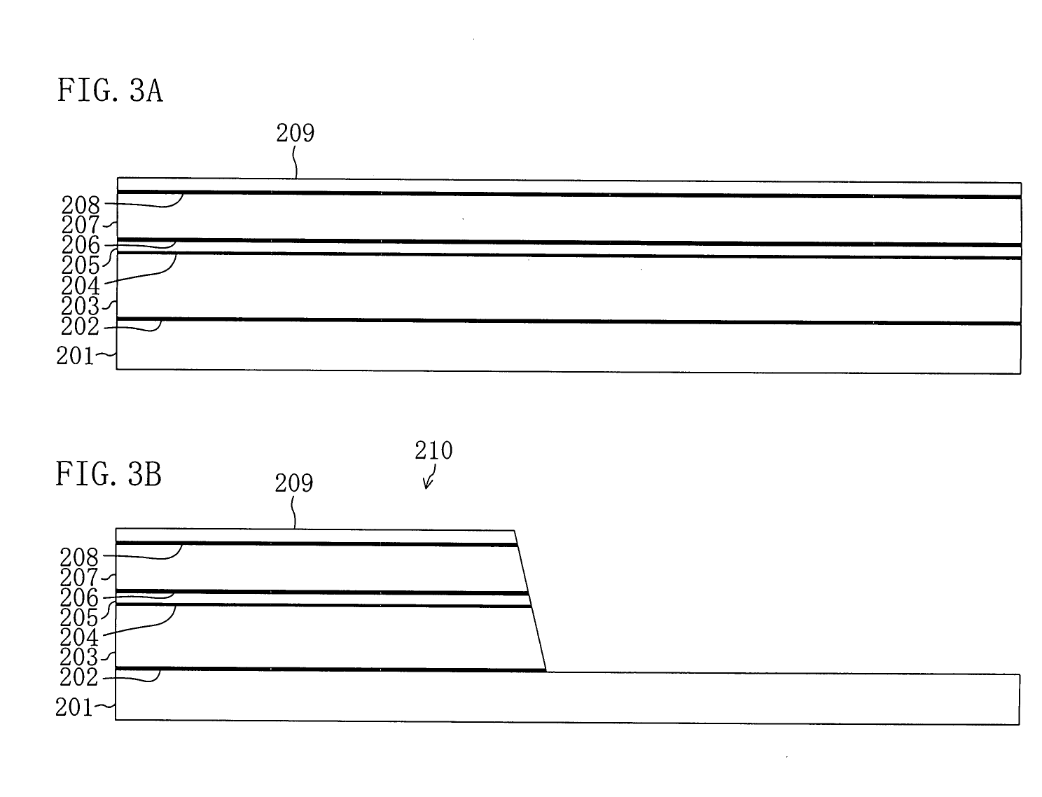

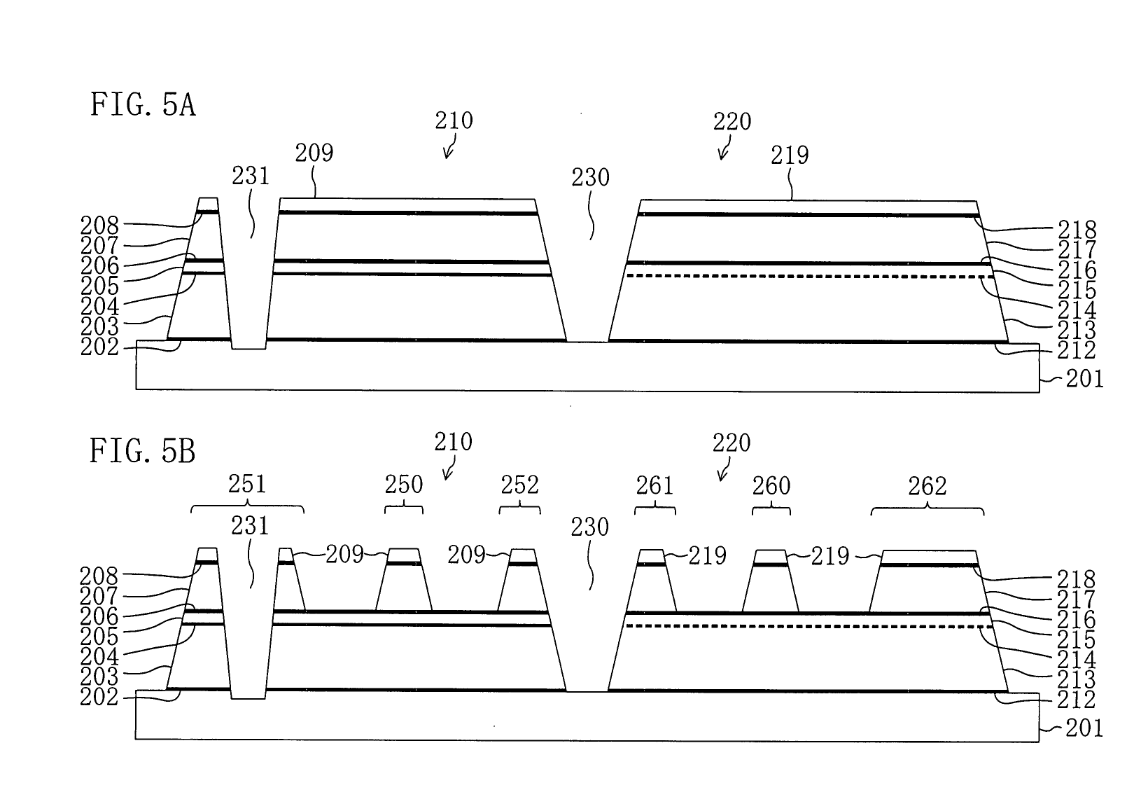

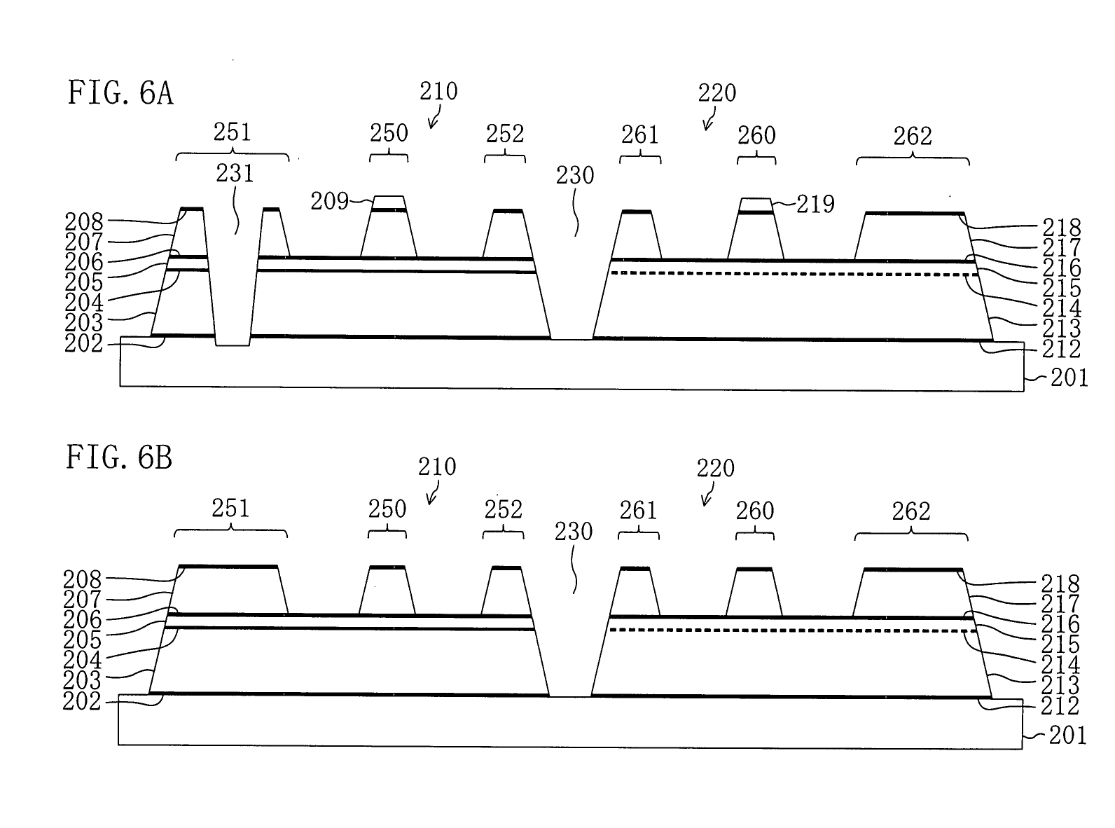

FIGS. 3A and 3B, FIG. 4, FIGS. 5A and 5B, FIGS. 6A and 6B, FIGS. 7A and 7B, FIGS. 8A and 8B and FIGS. 9A and 9B are cross-sectional views showing respective process steps of a method for fabricating a semiconductor laser device according to this embodiment. Cross-sectional structures of process steps up to the process step shown in FIG. 5B are the same between a region near the end faces of the resonators and the other region (hereinafter, referred to as a gain region) but are different between these regions in the subsequent process steps. Therefore, cross-sectional views showing the subsequent process steps are divided into the region near the end faces of the resonators and the gain region. That is, FIGS. 6A, 7A, 8A and 9A show cross-sectional structures of the gain region, and FIGS. 6B, 7B, 8B and 9B show cross-sectional structures near the end faces of the resonators associated with FIGS. 6A, 7A, 8A and 9A.

First, as illustrated in FIG. 3A, an n-type buffer layer 202 made of, for example, n-type GaAs, an n-type cladding layer 203 made of, for example, n-type (AlₓGa₁₋ₓ)_{y}In_{1-y}P (where 0<x<1 and 0<y<1), an active layer 204 made of, for example, a stack of a GaAs layer and an AlGaAs layer, a p-type first cladding layer 205 made of, for example, p-type (AlₓGa₁₋ₓ)_{y}In_{1-y}P (where 0<x<1 and 0<y<1), an etching stopper layer 206 made of, for example, p-type GaInP, a p-type second cladding layer 207 made of, for example, p-type (AlₓGa₁₋ₓ)_{y}In_{1-y}P (where 0<x<1 and 0<y<1), a p-type intermediate layer 208 made of, for example, p-type GaInP and a p-type contact layer 209 made of, for example, p-type GaAs are sequentially formed by, for example, MOCVD over an n-type substrate 201 made of, for example, n-type GaAs.

In this embodiment, the composition of (AlₓGa₁₋ₓ)_{y}In_{1-y}P in the cladding layers 203, 205 and 207 are set such that x=0.7 and y=0.5.

Next, as illustrated in FIG. 3B, a portion of the multilayer semiconductor structure formed in the process step shown in FIG. 3A associated with a red-laser region is removed by photolithography and wet etching, thereby forming an infrared-laser multilayer semiconductor structure 210. At this time, a hydrochloric acid-based etchant is used for etching of the semiconductor layers containing P and a sulfuric acid-based etchant is used for etching of the semiconductor layers containing As, thereby enhancing etching selectivity. This allows etching to be performed until a portion of the n-type substrate 201 associated with a red-laser region is exposed.

In the process step shown in FIG. 3A, when particles with a size of about 5 μm or more are adhered during crystal growth of, for example, the n-type buffer layer 202 or the n-type cladding layer 203, portions of the infrared-laser region where the particles are generated are not covered with a resist mask formed in the process step shown in FIG. 3B or photolithography in a subsequent process step in some cases. In such cases, the particles are removed by etching in the process step shown in FIG. 3B or a subsequent process step and the infrared-laser multilayer semiconductor structure 210 is removed by etching with an etchant entering the portion where the particles have been removed. As a result, a hole whose wall surface is oriented in the etching plane direction is disadvantageously formed to a depth reaching the n-type buffer layer 202 or the n-type substrate 201, for example. That is, this hole is formed in a case where particles are too large to be covered with the resist mask.

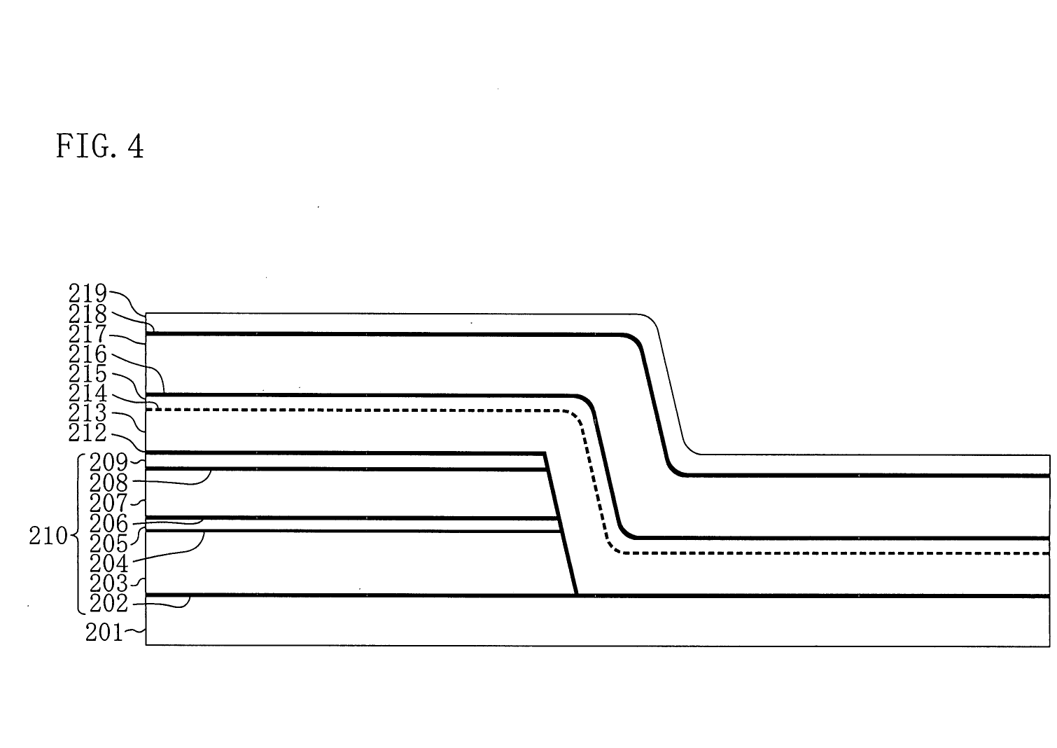

Then, as shown in FIG. 4, an n-type buffer layer 212 made of, for example, n-type GaAs, an n-type cladding layer 213 made of, for example, n-type (AlₓGa₁₋ₓ)_{y}In_{1-y}P (where 0<x<1 and 0<y<1), an active layer 214 made of, for example, a stack of a GaInP layer and an AlGaInP layer, a p-type first cladding layer 215 made of, for example, p-type (AlₓGa₁₋ₓ)_{y}In_{1-y}P (where 0<x<1 and 0<y<1), an etching stopper layer 216 made of, for example, p-type GaInP, a p-type second cladding layer 217 made of, for example, p-type (AlₓGa₁₋ₓ)_{y}In_{1-y}P (where 0<x<1 and 0<y<1), a p-type intermediate layer 218 made of, for example, p-type GaInP and a p-type contact layer 219 made of, for example, p-type GaAs are sequentially formed by, for example, MOCVD over the exposed surface of n-type substrate 201 in the red-laser region and the infrared-laser multilayer semiconductor structure 210.

In this embodiment, the composition of (AlₓGa₁₋ₓ)_{y}In_{1-y}P in the cladding layers 213, 215 and 217 are set such that x=0.7 and y=0.5.

Then, as illustrated in FIG. 5A, a portion of the multilayer semiconductor structure formed in the process step shown in FIG. 4 associated with an infrared-laser region (i.e., a portion formed on the infrared-laser multilayer semiconductor structure 210) is removed by photolithography and wet etching, thereby forming a red-laser multilayer semiconductor structure 220. At this time, since the semiconductor layers forming the red-laser multilayer semiconductor structure 220 contain P and As, a hydrochloric acid-based etchant and a sulfuric acid-based etchant are used as etchants. To electrically separate the infrared laser 110 and the red laser 120 from each other, an isolation trench 230 is formed between the infrared-laser multilayer semiconductor structure 210 and the red-laser multilayer semiconductor structure 220. At this time, trenches (hereinafter, also referred to as isolation trenches 230) are also formed between the multilayer semiconductor structures 210 and 220 and respective ends of the substrate.

In the process step shown in FIG. 4, when particles with a size of about 5 μm or more are adhered during crystal growth of, for example, the n-type buffer layer 212 or the n-type cladding layer 213, portions of the red-laser region where the particles are generated are not covered with a resist mask formed in the process step shown in FIG. 5A or photolithography in a subsequent process step in some cases. In such cases, the particles are removed by etching in the process step shown in FIG. 5A or a subsequent process step and the red-laser multilayer semiconductor structure 220 is also removed by etching with an etchant entering the portion where the particles have been removed. As a result, a hole whose wall surface is oriented in the etching plane direction is disadvantageously formed to a depth reaching the n-type buffer layer 212 or the n-type substrate 201, for example. That is, this hole is formed in a case where particles are too large to be covered with the resist mask.

In addition, as described above, in the process step shown in FIG. 5A, to remove, by etching, a portion of the multilayer semiconductor structure formed in the process step shown in FIG. 4 on the infrared-laser multilayer semiconductor structure 210, an etchant having high selectivity is used so as not to etch the infrared-laser multilayer semiconductor structure 210. However, in a case where particles with a size of, for example, about 5 μm or more are still present in the infrared-laser multilayer semiconductor structure 210 at the time of this etching, when the particles are removed by the etching, the infrared-laser multilayer semiconductor structure 210 made of the same material as the red-laser multilayer semiconductor structure 220 is also removed by etching with an etchant entering the portion where the particles have been removed. As a result, as shown in FIG. 5A, a hole 231 whose wall surface is oriented in the etching plane direction is disadvantageously formed to a depth reaching, for example, the n-type substrate 201 in the infrared-laser multilayer semiconductor structure 210.

Thereafter, a SiO₂ film (not shown), for example, is formed over the infrared-laser multilayer semiconductor structure 210 and the red-laser multilayer semiconductor structure 220, and then are patterned by photolithography and dry etching, thereby forming a mask pattern (not shown) covering a ridge-waveguide region in the shape of a stripe of each of the infrared laser 110 and the red laser 120 and also covering supporter regions at both sides of each of the ridge-waveguide regions. Subsequently, using the mask pattern, the p-type contact layer 209, the p-type intermediate layer 208 and the p-type second cladding layer 207 of the infrared laser and the p-type contact layer 219, the p-type intermediate layer 218 and the p-type second cladding layer 217 of the red laser are etched until the p-type etching stopper layer 206 and the p-type etching stopper layer 216 are exposed, thereby forming a ridge waveguide 250 of the infrared laser, supporters 251 and 252 at both sides of the ridge waveguide 250, a ridge waveguide 260 of the red laser and supporters 261 and 262 at both sides of the ridge waveguide 260, as illustrated in FIG. 5B.

In this embodiment, the etching process shown in FIG. 5B is performed by both dry etching using, for example, inductively coupled plasma or reactive ion plasma and wet etching.

Then, as illustrated in FIG. 6A, which is a cross-sectional view of the gain region, and FIG. 6B, which is a cross-sectional view near the end faces of the resonators, using photolithography and wet etching, the SiO₂ film and the p-type contact layer 209 are removed from the entire portions of the supporters 251 and 252 and a portion of the ridge waveguide 250 near the end face of the resonator, and the SiO₂ film and the p-type contact layer 219 are removed from the entire portions of the supporters 261 and 262 and a portion of the ridge waveguide 260 near the end face of the resonator. The removal of the SiO₂ film and the p-type contact layers 209 and 219 from the portions of the ridge waveguides 250 and 260 near the end faces of the resonators is performed within a range of, for example, 20 μm from the resonator end faces in the resonator direction (i.e., the direction along which the ridge waveguides 250 and 260 extend). The SiO₂ film is removed with, for example, a hydrogen fluoride-based etchant and the p-type contact layers 209 and 219 are removed with, for example, a sulfuric acid-based etchant.

In this embodiment, as shown in FIG. 6B, portions of the p-type contact layers 209 and 219 near the resonator end faces are removed in order to prevent damage to the lasers caused by heat generation at the resonator end faces during laser oscillation. In consideration of the accuracy in cleavage for forming the resonator end faces, the p-type contact layers 209 and 219 need to be removed within a range of at least 5 μm from the resonator end faces in the resonator direction. However, when the p-type contact layers 209 and 219 are excessively removed, the threshold value, for example, of current-light output characteristics of the lasers might vary due to an increase of resistance. In view of this, to suppress such characteristic variation, the range in removing the p-type contact layers 209 and 219 is preferably set at 80 μm or less from the resonator end faces in the resonator direction.

In addition, in this embodiment, as shown in FIGS. 6A and 6B, the p-type contact layers 209 and 219 are removed from the entire supporters 251 and 252 because of the following reasons. That is, if an n-type AlInP layer serving as a current blocking layer is grown on p-type GaAs forming the p-type contact layers 209 and 219 in a subsequent process step, crystallinity of this current blocking layer deteriorates so that surface morphology degrades. Accordingly, the alignment accuracy in photolithography for patterning the current blocking layer decreases. To prevent this decrease, the p-type contact layers 209 and 219 are removed from the entire supporters 251 and 252.

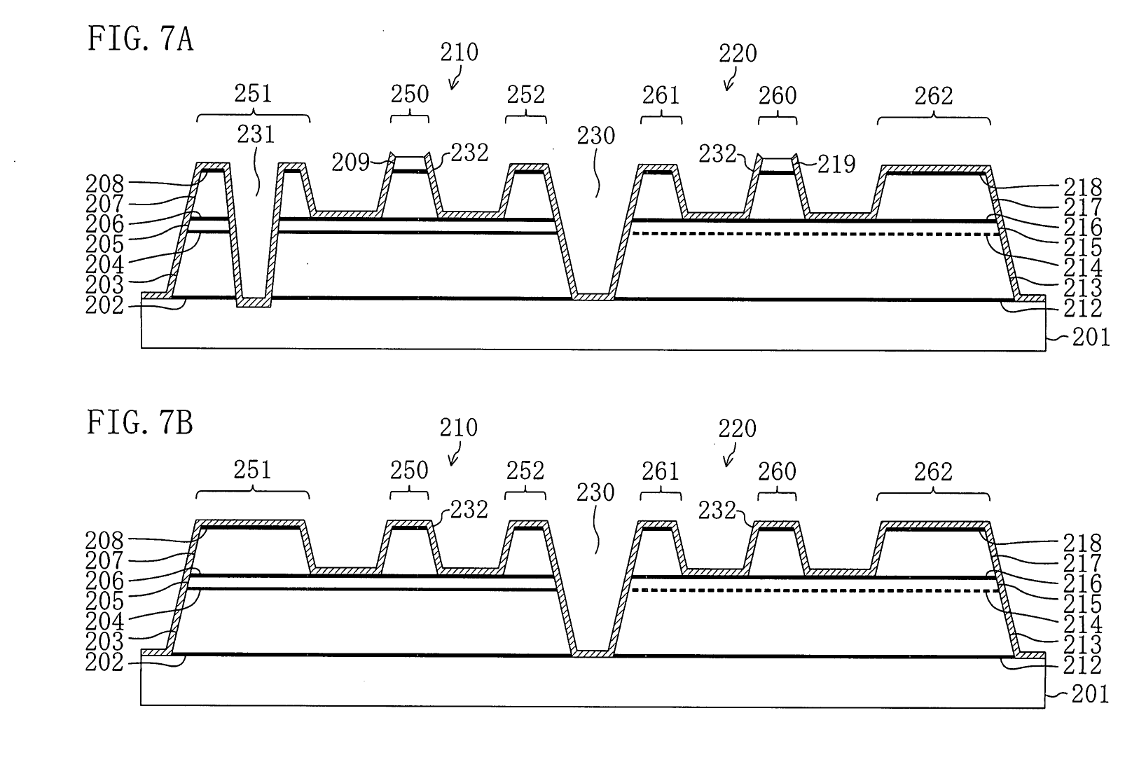

Thereafter, as shown in FIG. 7A, which is a cross-sectional view of the gain region, and FIG. 7B, which is a cross-sectional view near the end faces of the resonators, a current blocking layer 232 as a stack of, for example, an n-type AlInP layer and a p-type GaAs layer is selectively grown on the entire surface of the n-type substrate 201 using the SiO₂ film (not shown) remaining on the gain portions of the ridge waveguides 250 and 260 as a mask. At this time, since the SiO₂ film mask has been removed from portions of the ridge waveguides 250 and 260 near the resonator end faces as described above, the current blocking layer 232 is formed on the portions of the ridge waveguides 250 and 260 near the resonator end faces, as shown in FIG. 7B. In addition, as shown in FIG. 7A, the current blocking layer 232 is also formed in a hole 231 in the formation region thereof.

Subsequently, the SiO₂ film remaining on the gain portions of the ridge waveguides 250 and 260 is removed with, for example, a hydrogen fluoride-based etchant.

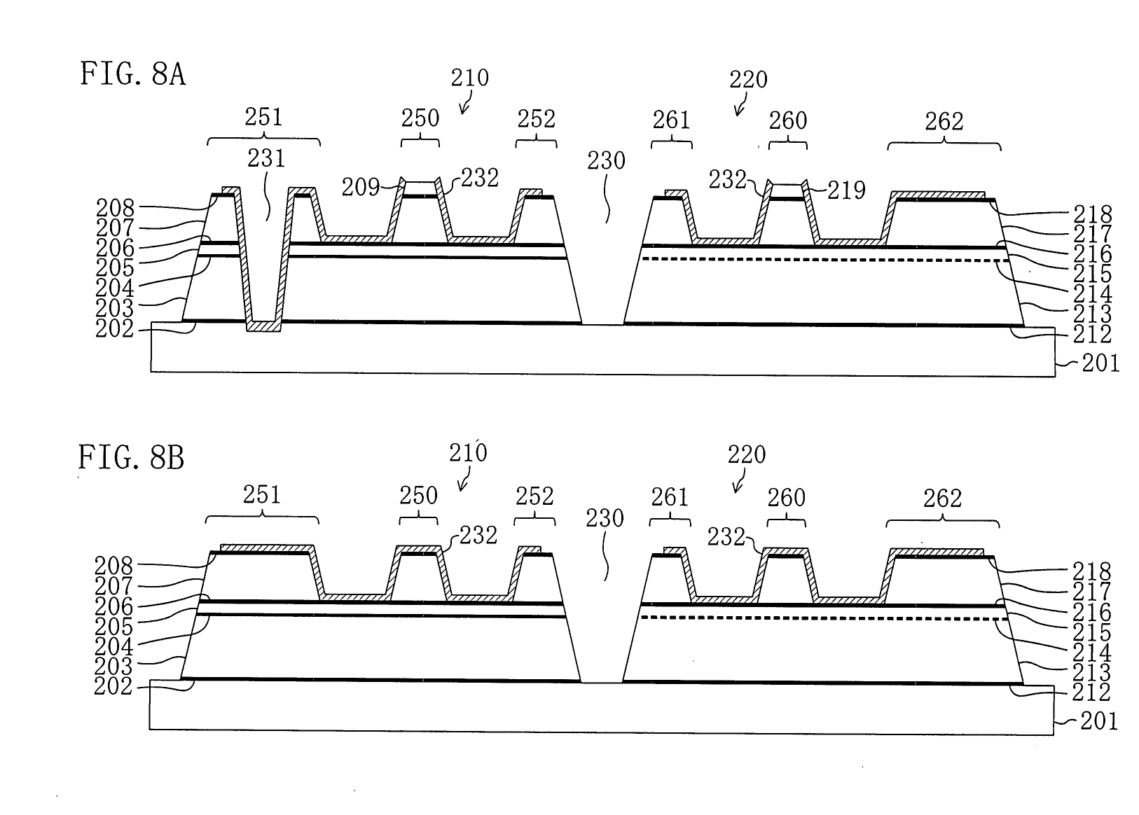

Then, as shown in FIG. 8A, which is a cross-sectional view of the gain region, and FIG. 8B, which is a cross-sectional view near the end faces of the resonators, portions of the current blocking layer 232 formed in the isolation trenches 230 (including the trenches at both ends of the device) and on their neighboring portions are removed by photolithography and etching. At this time, a hydrochloric acid-based etchant and a sulfuric acid-based etchant, for example, are used to remove the n-AlInP layer and the p-type GaAs layer forming the current blocking layer 232.

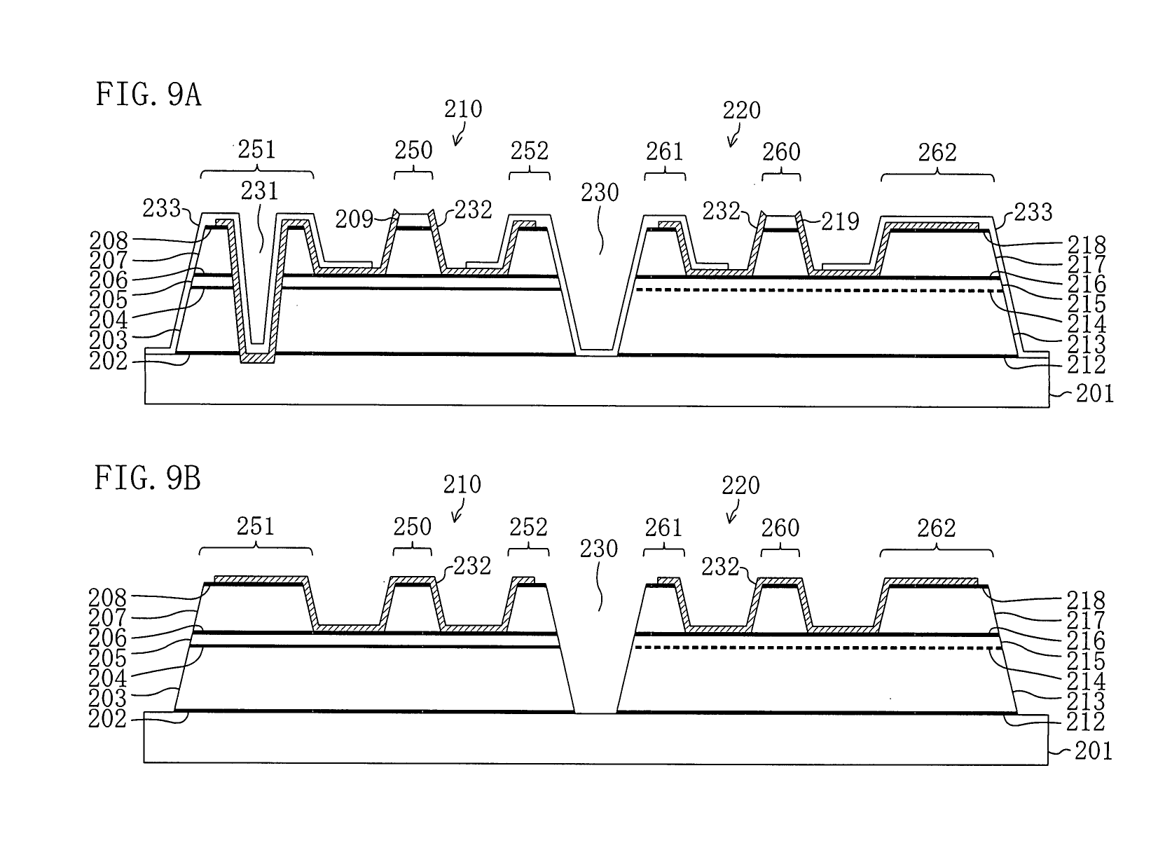

Then, as shown in FIG. 9A, which is a cross-sectional view of the gain region, and FIG. 9B, which is a cross-sectional view near the end faces of the resonators, a leakage preventing layer 233 made of, for example, a SiO₂ film with a thickness of 0.4 μm is formed over the entire surface of the n-type substrate 201 including the current blocking layer 232. Subsequently, portions of the leakage preventing layer 233 formed on the ridge waveguides 250 and 260 and on their neighboring regions and portions of the leakage preventing layer 233 near the end faces of the resonators are removed by photolithography and etching. In other words, the current blocking layer 232 is not covered with the leakage preventing layer 233 and is exposed near the ridge waveguides 250 and 260 and the end faces of the resonators. The SiO₂ film forming the leakage preventing layer 233 is removed with, for example, a hydrofluoric acid-based etchant. Portions of the leakage preventing layer 233 on the ridge waveguides 250 and 260 and their neighboring regions are removed within a range of, for example, 5 μm laterally (i.e., toward the sides of the substrate) from the ends of the ridge waveguides 250 and 260. It should be noted that the leakage preventing layer 233 is patterned such that the leakage preventing layer 233 remains on the supporters 251 and 252 and the supporters 261 and 262. Portions of the leakage preventing layer 233 near the end faces of the resonators are removed within a range of, for example, 5 μm from the resonator end faces in the resonator direction.

In this embodiment, as illustrated in FIG. 9A, in a region where the leakage preventing layer 233 is formed, the leakage preventing layer 233 is formed in the isolation trenches 230 in which the current blocking layer 232 is not formed and on its neighboring portion and the leakage preventing layer 233 is also formed in the hole 231 in which the current blocking layer 232 is formed.

Lastly, though not shown, a p-side electrode is formed at the surface of the n-type substrate 201 on which the multilayer semiconductor structures 210 and 220 are formed and an n-side electrode is formed at the back surface of the n-type substrate 201.

As described above, in this embodiment, in a monolithic multiwavelength laser device formed on the same substrate through a large number of etching processes, the following advantages are obtained. That is, since the leakage preventing layer 233 is formed on both side walls of each of the ridge waveguides 250 and 260, on the current blocking layer 232 formed around each of the ridge waveguides 250 and 260 and on other portions, even when etching, through a large number of etching processes, of particles generated during crystal growth of semiconductor layers forming the lasers causes a hole 231 to be formed in the semiconductor layers, the leakage preventing layer 233 is formed in this hole 231. Accordingly, the current blocking layer 232 is formed in the hole 231 even in a case where the hole 231 reaches the n-type substrate 201. Even if an electrode at the substrate surface side (i.e., a p-side electrode) is formed thereafter, the substrate-surface-side electrode and the current blocking layer 232 are insulated from each other by the leakage preventing layer 233, thereby preventing a short circuit failure from occurring between the substrate-surface-side electrode and an electrode at the substrate back surface side (i.e., an n-side electrode). That is, in the semiconductor laser device of this embodiment, a simple structure in which the leakage preventing layer 233 is formed on the current blocking layer 232 prevents a short circuit failure from occurring due to etching of particles generated during crystal growth. Accordingly, a monolithic multiwavelength semiconductor laser device which achieves a high yield at low cost is implemented.

In this embodiment, to obtain the foregoing advantages by sufficiently covering the hole 231 having a depth approximately equal to the height of each laser with the leakage preventing layer 233, the thickness of the leakage preventing layer 233 formed on the current blocking layer 232 is preferably 0.1 μm or more. To suppress increase of stress from the leakage preventing layer 233 to the current blocking layer 232, the thickness of the leakage preventing layer 233 is preferably 5 μm or less.

In this embodiment, a SiO₂ film is used as the leakage preventing layer 233. However, a material for the leakage preventing layer 233 is not specifically limited as long as the electrode at the substrate surface side and the current blocking layer 232 are electrically isolated from each other sufficiently enough to obtain the foregoing advantages. Specifically, one of single-layer films respectively made of Si, SiN, SiO₂, TiO₂, Ta₂O₅, NbO and amorphous Si hydride, which are materials having resistances of 3.0×10³ Ω·m or more, or a multilayer film as a stack of two or more of these single-layer films, for example, may be used as the leakage preventing layer 233.

In addition, in this embodiment, the stack of the n-type AlInP layer and the p-type GaAs layer is used as the current blocking layer 232. Alternatively, a stack of an n-type AlInP layer, a p-type GaAs layer and an n-type GaAs layer may be used, for example.

Further, in this embodiment, portions of the leakage preventing layer 233 are removed in a range of, for example, 5 μm from the ends of the ridge waveguides 250 and 260 laterally (i.e., in the direction towards each of the supporters 251, 252, 261 and 262). That is, to reduce stress from the leakage preventing layer 233 to the current blocking layer 232 so as to prevent reliability degradation of each laser, it is necessary to remove at least portions of the leakage preventing layer 233 located on the upper faces and side walls of the ridge waveguides 250 and 260. It is preferable to remove the leakage preventing layer 233 in a range of at least 1 μm from each end of the ridge waveguides 250 and 260 laterally. It should be noted that the leakage preventing layer 233 should not be removed beyond a range of 10 μm laterally from each end of the ridge waveguides 250 and 260 in order to ensure the advantage of this embodiment, i.e., the advantage that a short circuit failure caused by etching of particles generated at random during crystal growth is prevented.

Moreover, in this embodiment, portions of the leakage preventing layer 233 formed near the end faces of the resonators are removed, so that cleavage for forming the resonator end face of each laser is easily performed. Furthermore, in this embodiment, removal of portions of the leakage preventing layer 233 near the end faces of the resonators is performed in a range of 5 μm from the resonator end faces in the resonator direction. That is, to ensure the advantage that the cleavage is easily performed, the leakage preventing layer 233 should be removed in a range of at least 5 μm from the resonator end faces (more accurately, from the positions where the end faces of the resonators are to be formed before cleavage) in the resonator direction. It should be noted that the leakage preventing layer 233 should not be removed beyond a range of 20 μm from the resonator end faces (the same as described above) in the resonator direction in order to ensure the advantage of this embodiment, i.e., the advantage that a short circuit failure caused by etching of particles generated at random during crystal growth is prevented.

In this embodiment, in a region where the leakage preventing layer 233 is formed, the leakage preventing layer 233 is formed in the isolation trench 230 where the current blocking layer 232 is not formed and on its neighboring region, thus obtaining the following advantage. That is, even when solder flows into the isolation trench 230 after formation of a laser, the isolation trench 230 is covered with the leakage preventing layer 233, so that characteristic degradation of the laser is prevented.

In this embodiment, AlGaInP-based materials are used for the cladding layers 203, 205 and 207 for the infrared laser and the cladding layers 213, 215 and 217 for the red laser. Alternatively, GaAs-based materials may be used.

What is claimed is:

1. A semiconductor laser device which is a monolithic semiconductor laser device formed by integrating a first semiconductor laser emitting light with a first wavelength and a second semiconductor laser emitting light with a second wavelength on an identical substrate,
wherein each of the first semiconductor laser and the second semiconductor laser includes:
a doublehetero structure in which at least a first-conductivity-type cladding layer, an active layer and a second-conductivity-type cladding layer are stacked in this order; and
a ridge waveguide including at least an upper portion of the second-conductivity-type cladding layer and a contact layer formed on the second-conductivity-type cladding layer,
a first-conductivity-type current blocking layer is formed on both side walls of each of the ridge waveguides and on a portion around each of the ridge waveguides, and
a leakage preventing layer is formed on the current blocking layer.

2. The semiconductor laser device of claim 1, wherein a hole reaching at least the active layer is formed in the doublehetero structure of at least one of the first semiconductor laser and the second semiconductor laser.

3. The semiconductor laser device of claim 2, wherein the hole reaches the substrate.

4. The semiconductor laser device of claim 1, wherein the leakage preventing layer has a thickness of 0.1 μm or more.

5. The semiconductor laser device of claim 1, wherein the leakage preventing layer is one of single-layer films made of Si, SiN, SiO₂, TiO₂, Ta₂O₅, NbO and amorphous Si hydride, respectively, or a multilayer film made of a stack of two or more of the single-layer films.

6. The semiconductor laser device of claim 1, wherein the leakage preventing layer is deposited over the current blocking layer except for portions of the current blocking layer formed on both side walls of each of the ridge waveguides.

7. The semiconductor laser device of claim 6, wherein the leakage preventing layer is deposited over a portion of the current blocking layer at least 1 μm apart from each of the ridge waveguides.

8. The semiconductor laser device of claim 1, wherein the leakage preventing layer is also formed in a trench separating the first semiconductor laser and the second semiconductor laser from each other.

9. The semiconductor laser device of claim 1, wherein the leakage preventing layer has a resistivity of 3.0×10³ Ω·m or more.

10. The semiconductor laser device of claim 1, wherein the current blocking layer is a semiconductor layer.

11. The semiconductor laser device of claim 10, wherein the current blocking layer is a multilayer film formed by alternately stacking at least one n-type semiconductor layer and at least one p-type semiconductor layer.

12. The semiconductor laser device of claim 1, wherein the first-conductivity-type cladding layer and the second-conductivity-type cladding layer included in each of the first semiconductor laser and the second semiconductor laser are made of materials containing an identical element.

13. The semiconductor laser device of claim 1, wherein the first-conductivity-type cladding layer and the second-conductivity-type cladding layer included in each of the first semiconductor laser and the second semiconductor laser are made of materials containing phosphorus.

14. The semiconductor laser device of claim 1, wherein the light with the first wavelength is infrared light, and the light with the second wavelength is red light.

15. A semiconductor laser device which is a monolithic semiconductor laser device formed by integrating a first semiconductor laser emitting light with a first wavelength and a second semiconductor laser emitting light with a second wavelength on an identical substrate,
wherein each of the first semiconductor laser and the second semiconductor laser includes:
a doublehetero structure in which at least a first-conductivity-type cladding layer, an active layer and a second-conductivity-type cladding layer are stacked in this order;
a ridge waveguide including at least an upper portion of the second-conductivity-type cladding layer and a contact layer formed on the second-conductivity-type cladding layer; and
a supporter including at least an upper portion of the second-conductivity-type cladding layer and located at each side of the ridge waveguide at a given distance,
a first-conductivity-type current blocking layer is formed on both side walls of each of the ridge waveguides, on a side wall of each of the supporters toward an associated one of the ridge waveguides and between each of the supporters and an associated one of the ridge waveguides and, and
a leakage preventing layer is formed on the current blocking layer.

16. The semiconductor laser device of claim 15, wherein a hole reaching at least the active layer is formed in the doublehetero structure of at least one of the first semiconductor laser and the second semiconductor laser.

17. A method for fabricating a semiconductor laser device, the method comprising the steps of:
(a) forming a first multilayer semiconductor structure in which at least a first first-conductivity-type cladding layer, a first active layer, a first second-conductivity-type cladding layer and a first second-conductivity-type contact layer are stacked in this order over a first semiconductor laser region of a substrate;
(b) forming a second multilayer semiconductor structure in which at least a second first-conductivity-type cladding layer, a second active layer, a second second-conductivity-type cladding layer and a second second-conductivity-type contact layer are stacked in this order over a second semiconductor laser region of the substrate;
(c) patterning at least an upper portion of the first second-conductivity-type cladding layer and the first second-conductivity-type contact layer, thereby forming a first ridge waveguide, and patterning at least an upper portion of the second second-conductivity-type cladding layer and the second second-conductivity-type contact layer, thereby forming a second ridge waveguide;
(d) forming a current blocking layer on both side walls of the first ridge waveguide, a portion around the first ridge waveguide, both side walls of the second ridge waveguide and a portion around the second ridge waveguide; and
(e) forming a leakage preventing layer on the current blocking layer.

18. The method of claim 17, wherein the step (c) includes the step of forming a first supporter including at least an upper portion of the first second-conductivity-type cladding layer at each side of the fist ridge waveguide and forming a second supporter including at least an upper portion of the second second-conductivity-type cladding layer at each side of the second ridge waveguide.

19. The method of claim 18, further comprising, before the step (d), the step (f) of removing a portion of the first second-conductivity-type contact layer in the first ridge waveguide near an end face of a resonator of the first semiconductor laser, a portion of the first second-conductivity-type contact layer formed on the first supporter, a portion of the second second-conductivity-type contact layer in the second ridge waveguide near an end face of a resonator of the second semiconductor laser and a portion of the second second-conductivity-type contact layer formed on the second supporter.

20. The method of claim 17, further comprising, after the step (e), the step (g) of removing portions of the leakage preventing layer formed at least on both side walls of the first ridge waveguide and on both side walls of the second ridge waveguide.

21. The method of claim 20, wherein in the step (g), a portion of the leakage preventing layer in a range of 1 μm or more from each end of each of the first ridge waveguide and the second ridge waveguide is removed.

22. The method of claim 20, wherein in the step (g), a portion of the leakage preventing layer near an end face of a resonator of each of the first semiconductor laser and the second semiconductor laser is removed.

23. The method of claim 22, wherein in the step (g), a portion of the leakage preventing layer in a range from 5 μm to 20 μm, both inclusive, from an end face of a resonator of each of the first semiconductor laser and the second semiconductor laser is removed.

24. The method of claim 17, wherein in the step (e), the leakage preventing layer is also formed in a trench formed between the first multilayer semiconductor structure and the second multilayer semiconductor structure.
